(19) United States
(12) Patent Application Publication
(10) Pub. No.: US 2026/0213765 A1
(43) Pub. Date: Jul. 23, 2026

(54) DELTA-SIGMA MODULATOR AND CONTROL METHOD THEREOF

(71) Applicant: Asahi Kasei Microdevices Corporation, Tokyo (JP)

(72) Inventors: Kazuma OHARA, Tokyo (JP); Yuichi MIYAHARA, Tokyo (JP)

(73) Assignee: Asahi Kasei Microdevices Corporation, Tokyo (JP)

(21) Appl. No.: 19/034,943

(22) Filed: Jan. 23, 2025

(51) Int. Cl. H03M 3/00

(52) U.S. Cl. CPC H03M 3/436; H03M 3/422

(57) ABSTRACT

A delta-sigma modulator comprises: a first integrator configured to integrate an analog signal; a quantizer configured to quantize a signal output from the first integrator; a DA converter configured to convert a digital signal output from the quantizer into a feedback analog signal and output the feedback analog signal to the first integrator; and a controller configured to control the first integrator to repeatedly perform a series of integration operations. The series of integration operations includes at least a first integration operation and a second integration operation. The controller is configured to: control the first integrator to perform the first integration operation as an integrator having a first feedback coefficient; control the first integrator to perform the second integration operation as an integrator having a second feedback coefficient; and perform the first integration operation and the second integration operation at least partially simultaneously.

### TECHNICAL FIELD

The present disclosure relates to a delta-sigma modulator and a control method thereof.

### BACKGROUND

Conventionally, delta-sigma modulators are known as a technology for achieving high speed and high resolution. For example, US2019199369A1 disclose a delta-sigma modulator comprising an integrator that operates as an integrator having a feedback coefficient of 1 during a first period and operates as an amplifier having a feedback coefficient greater than 1 during a second period after the first period. In this conventional delta-sigma modulator, high filtering effect can be achieved by lengthening the first period. On the other hand, high resolution can be achieved by lengthening the second period.

### SUMMARY

However, the conventional incremental delta-sigma modulator requires to shorten the first period in order to lengthen the second period. Therefore, the conventional incremental delta-sigma modulator has a problem that lengthening the second period to improve resolution instead causes degradation in their filtering effect. It is, therefore, an object of the present disclosure to provide a delta-sigma modulator with improved resolution and filtering effect.

In order to achieve the object, one aspect of the present disclosure is a delta-sigma modulator comprising:
a first integrator configured to integrate an analog signal;
a quantizer configured to quantize a signal output from the first integrator;
a DA (Digital-to-Analog) converter configured to convert a digital signal output from the quantizer into a feedback analog signal and output the feedback analog signal to the first integrator; and
a controller configured to control the first integrator to repeatedly perform a series of integration operations.

The series of integration operations includes at least a first integration operation and a second integration operation.

The controller is configured to:
control the first integrator to perform the first integration operation as an integrator having a first feedback coefficient;
control the first integrator to perform the second integration operation as an integrator having a second feedback coefficient; and
perform the first integration operation and the second integration operation at least partially simultaneously.

Accordingly, the above-mentioned delta-sigma modulator can increase the number of the second integration operations without decreasing the number of the first integration operations. Therefore, the above-mentioned delta-sigma modulator can improve both the effect of the first integral action and the effect of the second integral action, for example, both high resolution and high filtering effect. Therefore, the present disclosure can provide a delta-sigma modulator with improved utility.

As used herein, the term “feedback coefficient” of an integrator generally refers to a gain of a feedback circuit arranged in a feedback path of the integrator. For example, if a feedback circuit that amplifies an input signal by a gain of x is arranged in a feedback path of an integrator, the integrator has the feedback coefficient of x. For example, if a feedback circuit that amplifies an input signal by a gain of 1 is arranged in the feedback path of the integrator, or if no feedback circuit is arranged in the feedback path of the integrator, the integrator has the feedback coefficient of 1.

As used herein, the term “a series of integration operations” generally refers to a set of integration operations that is repeatedly performed in a delta-sigma modulator. The series of integration operations included in a series of integration operations may be determined based on the design of the delta-sigma modulator. In the processing of the delta-sigma modulator, a reset period may be provided for performing a reset process to reset internal circuits such as integrators for each series of integration operations. In that case, a series of integration operations may refer to multiple integration operations executed between two reset periods. A series of integration operations may be executed according to the clock cycle used in the delta-sigma modulator. A series of integration operations may also be designed according to the sampling period and/or output rate of the delta-sigma modulator.

The series of integration operations includes at least a first integration operation and a second integration operation. As used herein, the term “first integration operation” generally refers to an integration operation performed by an integrator having a first feedback coefficient. As used herein, the term “second integration operation” generally refers to an integration operation performed by an integrator having a second feedback coefficient.

In the preceding delta-sigma modulator, the controller is preferably configured to apply an output signal from the first integration operation to the second integration operation.

In the preceding delta-sigma modulators, the first feedback coefficient is preferably greater than 0 and less than or equal to 1, and the second feedback coefficient is preferably greater than or equal to 1.

In the preceding delta-sigma modulators, the first feedback coefficient is preferably greater than 0 and less than 1.

In the preceding delta-sigma modulators, the second feedback coefficient is preferably greater than 1.

In the preceding delta-sigma modulators, the first feedback coefficient is preferably configured to be variable.

In the preceding delta-sigma modulators, the first integrator preferably comprises a variable capacitor, and the first feedback coefficient is preferably configured to be varied according to each integration operation included in the series of integration operations.

In the preceding delta-sigma modulators, the controller is preferably configured to: output a clock signal to the first integrator; and control the first integrator by associating the first integration operation and the second integration operation with respective half cycles of a clock cycle defined by the clock signal.

In the preceding delta-sigma modulators, the first integrator preferably comprises a first feedback capacitor and a second feedback capacitor. The controller is preferably configured to:
after executing the first integration operation using the first feedback capacitor, in a frontend sequence associated with a first half cycle of the clock cycle,
   start the second integration operation using the first feedback capacitor having a residual voltage generated by the first integral operation, in a backend sequence associated with a second half cycle of the clock cycle, and
   reset the second feedback capacitor and start the first integration operation using the reset second feedback capacitor, in the frontend sequence; and
after executing the first integration operation using the second feedback capacitor in the frontend sequence,
   start the second integration operation using the second feedback capacitor having a residual voltage generated by the first integral operation in the backend sequence, and
   reset the first feedback capacitor and start the first integration operation using the reset first feedback capacitor, in the frontend sequence.

The preceding delta-sigma modulators preferably further comprises: a second integrator configured to integrate the digital signal from the quantizer.

The preceding delta-sigma modulators preferably further comprises: an input terminal configured to receive an analog signal; and an adder-subtractor configured to subtract the feedback analog signal from the DA converter from the analog signal received at the input terminal to generate a subtracted analog signal and output the subtracted analog signal to the first integrator.

Another aspect of the present disclosure is a control method for a delta-sigma modulator, the delta-sigma modulator comprising:
a first integrator configured to integrate an analog signal;
a quantizer configured to quantize a signal output from the first integrator;
a DA (Digital-to-Analog) converter configured to convert a digital signal output from the quantizer into a feedback analog signal and output the feedback analog signal to the first integrator; and
a controller configured to control the first integrator to repeatedly perform a series of integration operations.

The series of integration operations includes at least a first integration operation and a second integration operation.

The control method comprises:
controlling, by the controller, the first integrator to perform the first integration operation as an integrator having a first feedback coefficient;
controlling, by the controller, the first integrator to perform the second integration operation as an integrator having a second feedback coefficient; and
performing, by the controller, the first integration operation and the second integration operation at least partially simultaneously.

Accordingly, the present disclosure can provide a delta-sigma modulator with improved resolution and filtering effect, and a control method thereof.

### BRIEF DESCRIPTION OF THE DRAWINGS

Various other objects, features, and attendant advantages of the present invention will become fully appreciated as the same becomes better understood when considered in conjunction with the accompanying drawings, in which like reference characters designate the same or similar parts throughout the several views, and wherein:

FIG. 1 illustrates a schematic configuration of a delta-sigma modulator according to an embodiment of the present disclosure;

FIG. 2 illustrates a configuration of the integrator in the delta-sigma modulator shown in FIG. 1;

FIG. 3 is a diagram illustrating the sequential operations of the delta-sigma modulator shown in FIG. 1;

FIG. 4 is a graph illustrating the transfer functions of the first integration operation and the second integration operation in the sequential operations shown in FIG. 3;

FIG. 5 is a graph illustrating the transfer functions with different numbers of second integration operations in the sequential operation shown in FIG. 3;

FIG. 6 is a diagram illustrating the parallel operations of the delta-sigma modulator shown in FIG. 1;

FIG. 7 is a graph comparing the transfer function of the sequential operation shown in FIG. 3 and the parallel operation shown in FIG. 6;

FIG. 8 illustrates an example of a circuit configuration of the first integrator in the delta-sigma modulator shown in FIG. 1; and

FIG. 9 shows an example of the parallel operations of the first integrator shown in FIG. 8.

### DETAILED DESCRIPTION

A delta-sigma modulator 1 and a control method thereof according to an embodiment of the present disclosure will be described below with reference to the accompanying drawings. In the following description of the present embodiment, the description of the same or corresponding parts will be omitted or simplified as appropriate. In each drawing, the same reference characters designate the same or corresponding parts.

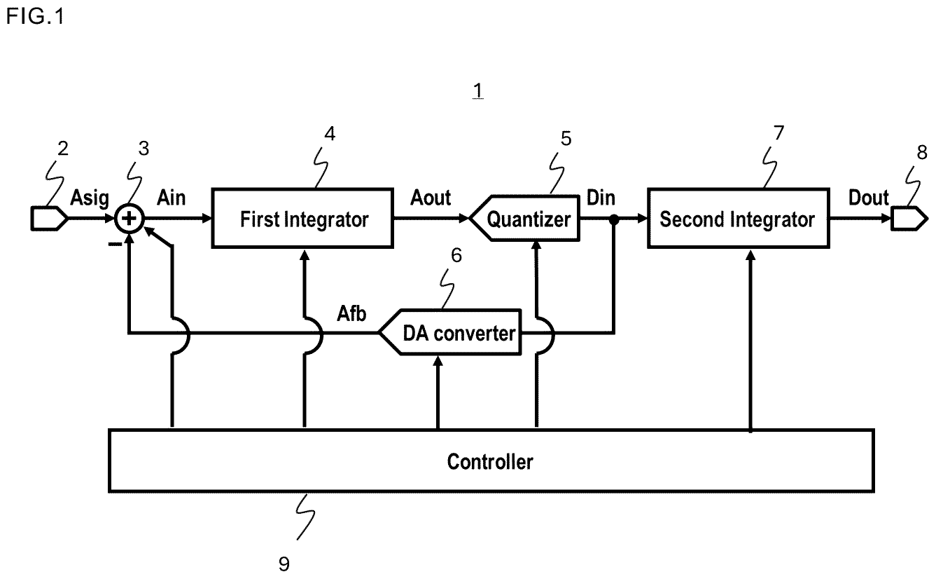

At first, with reference to FIG. 1, a configuration of a delta-sigma modulator 1 according to the present embodiment will be described. FIG. 1 illustrates a schematic configuration of the delta-sigma modulator 1.

The delta-sigma modulator 1 comprises an input terminal 2, an adder-subtractor 3, a first integrator 4, a quantizer 5, a DA converter 6 (Digital-to-Analog converter 6), a second integrator 7, an output terminal 8, and a controller 9. The delta-sigma modulator 1 is an incremental-type AD converter (Analog-to-Digital converter) that converts the analog signal Asig input to the input terminal 2 into a digital signal Dout with resetting internal circuits and outputs the digital signal Dout from the output terminal 8. Therefore, the delta-sigma modulator 1 is an incremental delta-sigma modulator.

The input terminal 2 receives an analog signal Asig. In the present embodiment, the input terminal 2 is connected to the adder-subtractor 3. The input terminal 2 is configured to be connectable to an external device located outside the delta-sigma modulator 1. The input terminal 2 receives the analog signal Asig input from the external device. The input terminal 2 outputs the received analog signal Asig to the adder-subtractor 3.

The adder-subtractor 3 subtracts the feedback analog signal Afb from the DA converter 6 from the analog signal Asig received at the input terminal 2 to generate a subtracted analog signal Ain and outputs the subtracted analog signal Ain to the first integrator 4. In the present embodiment, the adder-subtractor 3 is connected to the input terminal 2, the first integrator 4, and the DA converter 6. The adder-subtractor 3 receives the analog signal Asig from the input terminal 2 and the feedback analog signal Afb from the DA converter 6. The adder-subtractor 3 subtracts the feedback analog signal Afb from the analog signal Asig to generate the analog signal Ain. The adder-subtractor 3 may perform this subtraction in accordance with the clock signal supplied by the controller 9. The adder-subtractor 3 outputs the generated analog signal Ain to the first integrator 4.

The first integrator 4 is an analog integrator having a first-order or higher-order feedback coefficient. The first integrator 4 integrates the analog signal Ain. In the present embodiment, the first integrator 4 is connected to the adder-subtractor 3 and the quantizer 5. The first integrator 4 receives the analog signal Ain from the adder-subtractor 3. The first integrator 4 integrates the analog signal Ain to generate an analog signal Aout. The first integrator 4 may integrate the analog signal Ain in accordance with a clock signal supplied by the controller 9. The first integrator 4 outputs the generated analog signal Aout to the quantizer 5.

The quantizer 5 quantizes the signal Aout output from the first integrator 4. In the present embodiment, the quantizer 5 is connected to the first integrator 4, the DA converter 6, and the second integrator 7. The quantizer 5 receives the analog signal Aout from the first integrator 4. The quantizer 5 quantizes the analog signal Aout to generate a digital signal Din. The quantizer 5 may quantize the analog signal Aout in accordance with a clock signal supplied by the controller 9. The quantizer 5 outputs the generated digital signal Din to the DA converter 6 and the second integrator 7. The quantizer 5 may be a 1-bit quantizer configured to output a binary digital signal Alternatively, the quantizer 5 may be a multi-bit quantizer configured to output a multi-value digital signal.

The DA converter 6 converts the digital signal Din from the quantizer 5 into a feedback analog signal Afb. In the present embodiment, the DA converter 6 is connected to the adder-subtractor 3 and the quantizer 5. The DA converter 6 receives the digital signal Din from the quantizer 5. The DA converter 6 performs DA conversion (Digital-to-Analog conversion) of the received digital signal Din to generate the feedback analog signal Afb. The DA converter 6 may perform the DA conversion in accordance with a clock signal supplied by the controller 9. The DA converter 6 outputs the generated feedback analog signal Afb to the adder-subtractor 3. The feedback analog signal Afb from the DA converter 6 is input to the first integrator 4 via the adder-subtractor 3. That is, the DA converter 6 converts the digital signal Din output from the quantizer 5 into a feedback analog signal Afb and outputs the feedback analog signal Afb to the first integrator 4.

The second integrator 7 is an analog integrator having a first-order or higher-order feedback coefficient. The second integrator 7 integrates the digital signal Din from the quantizer 5. In the present embodiment, the second integrator 7 is connected to the quantizer 5 and the output terminal 8. The second integrator 7 receives the digital signal Din from the quantizer 5. The second integrator 7 integrates the received digital signal Din to generate a digital signal Dout. The second integrator 7 may integrate the digital signal Din in accordance with a clock signal supplied by the controller 9. The second integrator 7 outputs the generated digital signal Dout to the output terminal 8.

The output terminal 8 outputs a digital signal Dout. In the present embodiment, the output terminal 8 is connected to the second integrator 7. The output terminal 8 is configured to be connectable to an external device located outside the delta-sigma modulator 1. The output terminal 8 receives the digital signal Dout from the second integrator 7. The output terminal 8 outputs the received digital signal Dout to the external device.

The controller 9 includes one or more control circuits. The controller 9 is communicatively connected to each component included in the delta-sigma modulator 1, such as the input terminal 2, the adder-subtractor 3, the first integrator 4, the quantizer 5, the DA converter 6, the second integrator 7, and the output terminal 8. Accordingly, the controller 9 controls the operations of the delta-sigma modulator 1. Therefore, the following description of the operation of the delta-sigma modulator 1 also serves as an explanation of the control method for the delta-sigma modulator 1 executed by the control unit 9. For example, the controller 9 controls the first integrator 4 and the second integrator 7 to repeatedly perform a series of integration operations.

For example, the controller 9 transmits a clock signal to the adder-subtractor 3, the first integrator 4, the quantizer 5, the DA converter 6, and the second integrator 7 to control the timing of their operations. As a result, the controller 9 causes the adder-subtractor 3, the first integrator 4, the quantizer 5, the DA converter 6, and the second integrator 7 to execute processing in clock cycles. The clock signal may be supplied to the controller 9 from an external device located outside the delta-sigma modulator 1. Alternatively, the controller 9 may comprise a clock oscillator to generate a clock signal.

Further, for example, the controller 9 transmits a reset signal for resetting the integrated value to each of the first integrator 4 and the second integrator 7. Upon receiving the reset signal from the controller 9, each of the first integrator 4 and the second integrator 7 performs a reset operation to reset the integrated value held by each of them. The controller 9 may transmit the reset signal to each of the first integrator 4 and the second integrator 7 either before starting a series of integration operations or after completing a series of integration operations. The controller 9 resets each of the first integrator 4 and the second integrator 7 for each series of integration operations.

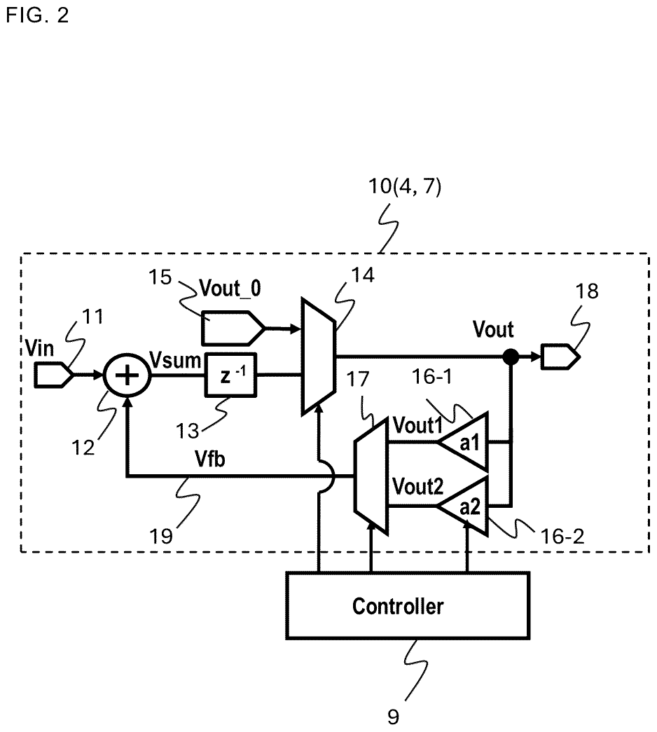

Next, with reference to FIG. 2, configurations of the first integrator 4 and the second integrator 7 in the delta-sigma modulator 1 will be described. FIG. 2 illustrates a configuration of the integrator 10 (first integrator 4, second integrator 7) in the delta-sigma modulator 1 shown in FIG. 1. In the present disclosure, the first integrator 4 and the second integrator 7 are collectively referred to simply as “integrator 10” when they are not distinguished from each other.

As shown in FIG. 2, the integrator 10 receives a signal Vin. The integrator 10 integrates the received signal Vin to generate a signal Vout. Then, the integrator 10 outputs the integrated signal Vout. If the integrator 10 is an analog integrator (first integrator 4), the signals Vin and Vout are analog signals. If the integrator 10 is a digital integrator (second integrator 7), the signals Vin and Vout are digital signals.

The integrator 10 includes an input terminal 11, an adder 12, a delay circuit 13, a first switch circuit 14, a reset circuit 15, a first feedback circuit 16-1, a second feedback circuit 16-2, a second switch circuit 17, and an output terminal 18. The integrator 10 has a feedback path 19 configured to feed back the output Vout from the first switch circuit 14 to the adder 12.

The input terminal 11 is connected to the adder 12. The input terminal 11 receives the signal Vin. The input terminal 11 outputs the received signal Vin to the adder 12.

The adder 12 is connected to the input terminal 11, the delay circuit 13, and the second switch circuit 17. The adder 12 receives the signal Vin input to the input terminal 11 and the feedback signal Vfb from the second switch circuit 17. The adder 12 adds the signal Vin and the feedback signal Vfb to generate the signal Vsum. The adder 12 outputs the generated signal Vsum to the delay circuit 13.

The delay circuit 13 is connected to the adder 12 and the first switch circuit 14. The delay circuit 13 receives the signal Vsum from the adder 12. The delay circuit 13 delays the received signal Vsum and outputs it to the first switch circuit 14. The delay circuit 13 has the transfer function Z⁻¹.

The first switch circuit 14 is connected to the delay circuit 13, the reset circuit 15, the first feedback circuit 16-1, the second feedback circuit 16-2, and an output terminal 18. The first switch circuit 14 is communicatively connected to the controller 9. The first switch circuit 14 receives the signal from the delay circuit 13 and the signal from the reset circuit 15. The first switch circuit 14 outputs one of the signal from the delay circuit 13 and the signal from the reset circuit 15, as a signal Vout, to the first feedback circuit 16-1, second feedback circuit 16-2, and the output terminal 18. The first switch circuit 14 switches the output in accordance with a reset signal supplied by the controller 9. Upon receiving a reset signal, the first switch circuit 14 outputs the signal from the reset circuit 15 as the signal Vout. Upon not receiving a reset signal, the first switch circuit 14 outputs the signal from the delay circuit 13 as the signal Vout.

The reset circuit 15 is connected to the first switch circuit 14. The reset circuit 15 outputs an initial signal Vout_0 to the first switch circuit 14. The initial signal Vout_0 is an initial value of the output of the integrator 10, and is set to, for example, a common voltage (0 V).

The first feedback circuit 16-1 is connected to the first switch circuit 14 and the second switch circuit 17. The first feedback circuit 16-1 is communicatively connected to the controller 9. The first feedback circuit 16-1 is placed on the feedback path 19. The first feedback circuit 16-1 amplifies the signal Vout from the first switch circuit 14 by a gain of a1 and outputs the amplified signal to the second switch circuit 17. Specifically, the first feedback circuit 16-1 receives the signal Vout from the first switch circuit 14. The first feedback circuit 16-1 amplifies the received signal Vout by a gain of a1 to generate a signal Vout1. The first feedback circuit 16-1 outputs the generated signal Vout1 to the second switch circuit 17.

The second feedback circuit 16-2 is connected to the first switch circuit 14 and the second switch circuit 17. The second feedback circuit 16-2 is communicatively connected to the controller 9. The second feedback circuit 16-2 is placed on the feedback path 19. The second feedback circuit 16-2 amplifies the signal Vout from the first switch circuit 14 by a gain of a2 and outputs the amplified signal to the second switch circuit 17. Specifically, the second feedback circuit 16-2 receives the signal Vout from the first switch circuit 14. The second feedback circuit 16-2 amplifies the received signal Vout by a gain of a2 to generate a signal Vout2. The second feedback circuit 16-2 outputs the generated signal Vout2 to the second switch circuit 17.

The second switch circuit 17 is connected to the adder 12, the first feedback circuit 16-1, and the second feedback circuit 16-2. The second switch circuit 17 is communicatively connected to the controller 9. The second switch circuit 17 receives the signal Vout1 from the first feedback circuit 16-1 and the signal Vout2 from the second feedback circuit 16-2. The second switch circuit 17 outputs the signal Vout1 from the first feedback circuit 16-1, the signal Vout2 from the second feedback circuit 16-2, or a signal obtained by adding the signals Vout1 and Vout2 to the adder 12, as a feedback signal Vfb.

The second switch circuit 17 switches the output according to a control signal from the controller 9. The control signal includes a first control signal and a second control signal. Upon receiving the first control signal, the second switch circuit 17 outputs the signal Vout1 from the first feedback circuit 16-1 as a feedback signal Vfb. As a result, upon receiving the first control signal, the integrator 10 operates as an integrator having a first feedback coefficient a1. That is, the controller 9 controls the integrator 10 to perform a first integration operation as an integrator having the first feedback coefficient a1. The gain a1 of the first feedback circuit 16-1 may be greater than 0 and less than or equal to 1. That is, the first feedback coefficient a1 may be greater than 0 and less than or equal to 1. Preferably, the gain a1 may be greater than 0 and less than 1. That is, the first feedback coefficient a1 may be greater than 0 and less than 1.

Upon receiving the second control signal, the second switch circuit 17 outputs the signal Vout2 from the second feedback circuit 16-2 as a feedback signal Vfb. As a result, upon receiving the second control signal, the integrator 10 operates as an integrator having a second feedback coefficient a2. That is, the controller 9 controls the integrator 10 to perform a second integration operation as an integrator having the second feedback coefficient a2. The gain a2 of the second feedback circuit 16-2 may be greater than or equal to 1. That is, the second feedback coefficient a2 may be greater than or equal to 1. Preferably, the gain a2 may be greater than 1. That is, the second feedback coefficient a2 may be greater 1.

Upon receiving both the first control signal and the second control signal, the second switch circuit 17 outputs a signal obtained by adding the signal Vout1 from the first feedback circuit 16-1 and the signal Vout2 from the second feedback circuit 16-2 as the feedback signal Vfb. As a result, the controller 9 performs the first integration operation and the second integration operation at least partially simultaneously.

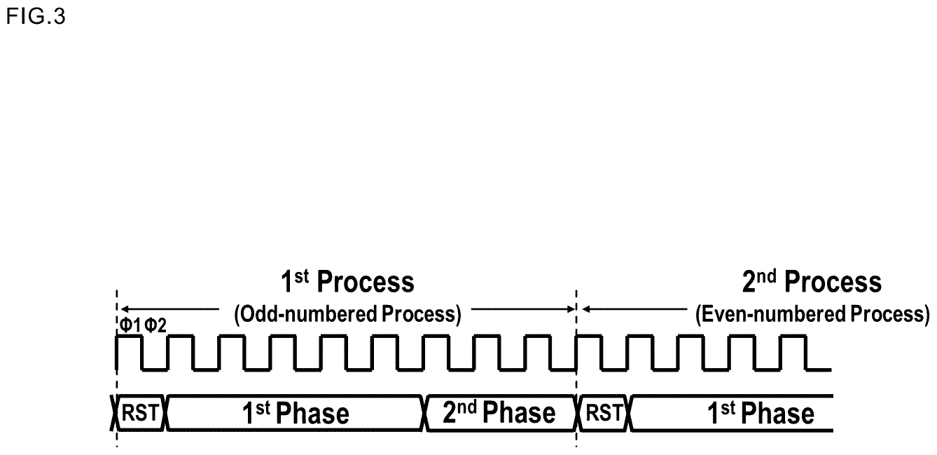

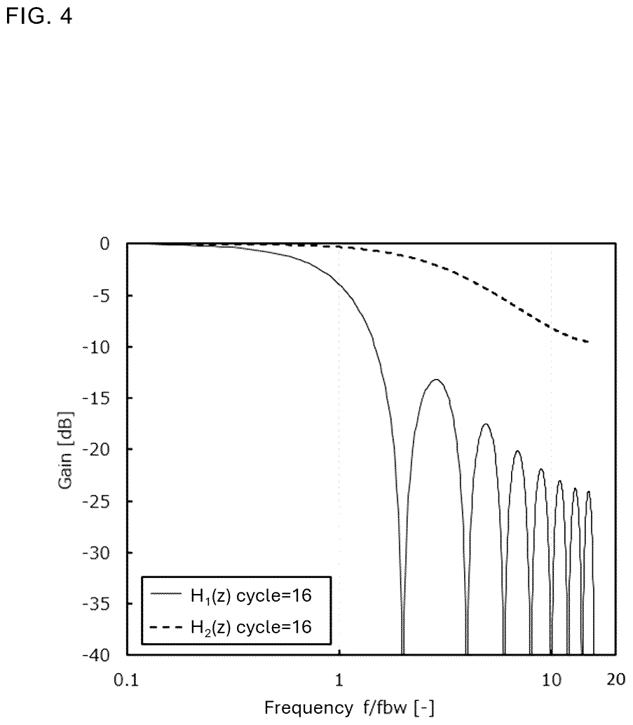

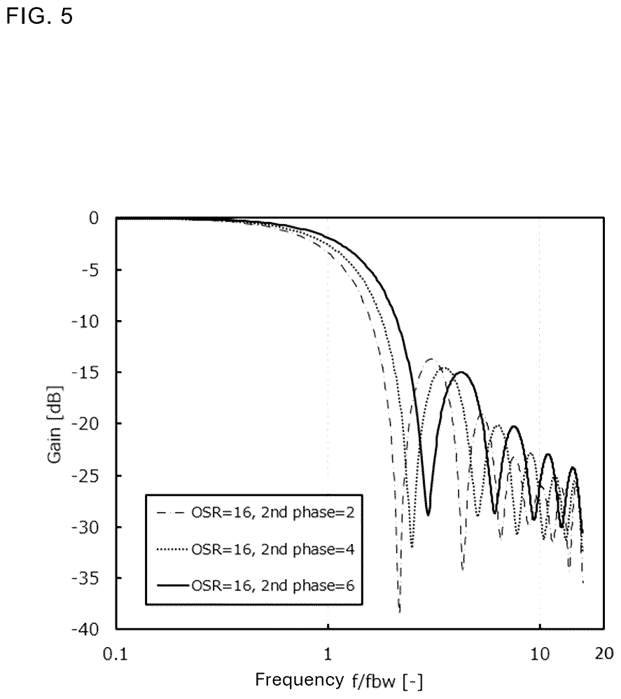

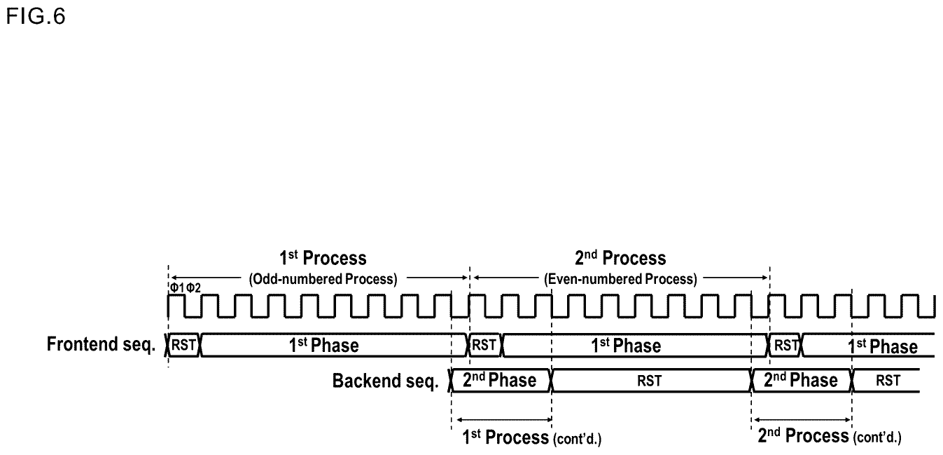

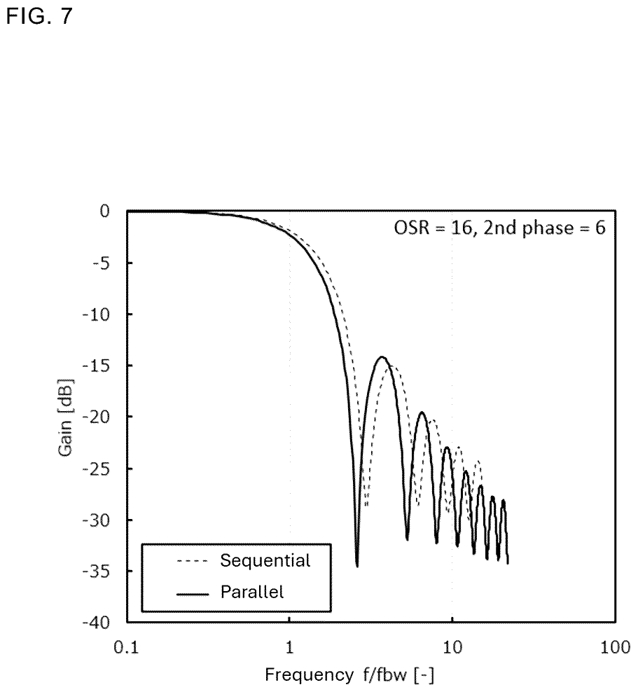

With reference to FIG. 3, FIG. 4, FIG. 5, FIG. 6, and FIG. 7, the operation of the delta-sigma modulator 1 according to the present disclosure will be described. The operation of the delta-sigma modulator 1 includes a series of integration operations and a reset operation that are repeatedly performed. The series of integration operations and the reset operation are also referred to as an “integration process.” That is, an integration process includes a series of integration operations and a reset operation. The series of integration operations includes at least a first integration operation and a second integration operation. The integration process is a unit of operation that is repeatedly performed in the delta-sigma modulator 1. In the following description, each integration process includes a reset phase, a first processing phase, and a second processing phase. The reset phase is a period during which the reset operation is performed. The reset phase is also referred to as a reset period. The first processing phase is a period during which one or more first integration operations are performed. The second processing phase is a period during which one or more second integration operations are performed.

First, with reference to FIG. 3, the sequential operation of the delta-sigma modulator 1 will be described. FIG. 3 is a diagram illustrating the sequential operations of the delta-sigma modulator 1. The delta-sigma modulator 1 performs the sequential operations corresponding to two phases, φ1 and φ2 (for example, high/low), which repeat within each clock cycle. As shown in FIG. 3, in the sequential operation, the delta-sigma modulator 1 sequentially repeats an integration process including a reset phase, a first processing phase, and a second processing phase. The controller 9 controls each of the first integrator 4 and the second integrator 7 to repeatedly perform the integration process including the reset phase, the first processing phase, and the second processing phase for each predetermined period.

In FIG. 3, as an example, the delta-sigma modulator 1 performs a reset operation in the reset phase over 1 clock, then performs a series of integration operations in the first and second processing phases over 8 clocks, and outputs the result. Therefore, the oversampling ratio OSR of the delta-sigma modulator 1 in FIG. 3 is 8. Here, the oversampling ratio of the delta-sigma modulator 1 represents the number of times the input signal is sampled during one cycle at the output rate of the delta-sigma modulator 1. The oversampling ratio may be equal to the number of integration operations included in a series of integration operations.

In the reset phase, the controller 4 controls the first integrator 4 and the second integrator 7 to perform a reset operation to reset the integration values held by each of the first integrator 4 and the second integrator 7. In the first processing phase, the controller 4 controls the first integrator 4 and the second integrator 7 to execute a first integration operation as an integrator having a first feedback coefficient a1. In the second processing phase, the controller 4 controls the first integrator 4 and the second integrator 7 to execute a second integration operation as an integrator having a second feedback coefficient a2, with the output in the first processing phase remaining as a residual component. That is, in the second processing phase, the controller 4 applies the output signal from the first integration operation to the second integration operation. When the number of first integration operations in the first processing phase is n and the number of second integration operations in the second processing phase is m, then n+m=OSR holds in the sequential operation.

In the first processing phase, the analog signal Aout output from the first integrator 4 by the first integration operations is derived from the following equations (1) to (3).

$${A}_{i n} ( z ) = {A}_{s i g} ( z ) - {A}_{fb} ( z ) \qquad ( 1 )$$

$${A}_{o u t} ( z ) = {a}_{1} {z}^{- 1} ( {A}_{i n} ( z ) + {A}_{out} ( z ) ) \qquad ( 2 )$$

$${A}_{o u t} ( z ) = \frac{{z}^{- 1}}{1 - {a}_{1} {z}^{- 1}} ( {A}_{i n} ( z ) ) \qquad ( 3 )$$

Here, Asig represents the analog signal received by delta-sigma modulator 1, Ain represents the analog signal input to the first integrator 4, Afb represents the feedback analog signal from the DA converter 6, and Aout represents the analog signal output from the first integrator 4, z represents a complex variable, z⁻¹ represents a delay in the delay circuit 13, and a1 represents the first feedback coefficient.

From equation (3), the transfer function H1 of the first integrator 4 in the first integration operation in the first processing phase is expressed by the following equation (4). The transfer function H1 of the second integrator 7 is also expressed by equation (4).

$${H}_{1} ( z ) = \frac{{z}^{- 1}}{1 - {a}_{1} {z}^{- 1}} \qquad ( 4 )$$

Here, z represents a complex variable, z⁻¹ represents a delay in the delay circuit 13, and a1 represents the first feedback coefficient.

Assuming that the DA converter 6 operates ideally, the digital signal Din output from the quantizer 5 and the feedback analog signal Afb from the DA converter 6 can be the same value, and therefore the following equation (5) is established.

$${A}_{o u t} ( z ) = ( \frac{{z}^{- 1}}{1 - {a}_{2} {z}^{- 1}} ) ( {A}_{s i g} ( z ) - {D}_{i n} ( z ) ) \qquad ( 5 )$$

Therefore, the digital signal Dout output from the delta-sigma modulator 1 in the first processing phase is derived by the following equations (6) to (10).

$${D}_{i n} ( z ) = {A}_{sig} ( z ) - {A}_{o u t} ( z ) \frac{1 - {a}_{1} {z}^{- 1}}{{z}^{- 1}} \qquad ( 6 )$$

$${D}_{o u t} ( z ) = \frac{{z}^{- 1}}{1 - {a}_{1} {z}^{- 1}} ( {D}_{i n} ( z ) ) \qquad ( 7 )$$

$${D}_{o u t} ( z ) = ( \frac{{z}^{- 1}}{1 - {a}_{2} {z}^{- 1}} ) ( {A}_{s i g} ( z ) - {A}_{o u t} ( z ) \frac{1 - {a}_{1} {z}^{- 1}}{{z}^{- 1}} ) \qquad ( 8 )$$

$${D}_{o u t} ( z ) = ( \frac{{z}^{- 1}}{1 - {a}_{2} {z}^{- 1}} ) {A}_{sig} ( z ) - {A}_{out} ( z ) \qquad ( 9 )$$

Here, as shown in FIG. 1, Din represents the digital signal input to the second integrator 7 and Dout represents the digital signal output from the second integrator 7.

Moreover, when the initial values of the output signal Aout from the first integrator 4 and the output signal Dout from the second integrator 7 are 0, and the analog signal Asig input to the delta-sigma modulator 1 is a substantially constant value, the digital signal Dout[n] in the first processing phase is expressed by the following equation (10).

$${D}_{out} [ n ] = {{\sum }_{i = 1}}^{n} {A}_{sig} - {A}_{out} [ n ] = n {A}_{s i g} - {A}_{o u t} [ n ] \qquad ( 10 )$$

Here, Dout[i] represents the the i-th output (i>0) and n represents the number of the first integration operation performed in the first processing phase.

As shown in equation (10), the digital signal Dout output from the delta-sigma modulator 1 can be expressed using the input analog signal Asig. In addition, in equation (10), the number n, which represents the number of first integration operations in the first processing phase, is the coefficient of Asig. That is, when the number of first integration operations in the first processing phase is n, the resolution of the delta-sigma modulator 1 is on the order of n times Asig.

In the second processing phase, the analog signal Aout output from the first integrator 4 by the second integration operations is expressed by the following equation (11).

$${A}_{o u t} ( z ) = \frac{{z}^{- 1}}{1 - {a}_{2} {z}^{- 1}} ( {A}_{i n} ( z ) ) \qquad ( 11 )$$

From equation (11), the transfer function H2 of the first integrator 4 in the second integration operation in the second processing phase is expressed by the following equation (11). The transfer function H2 of the second integrator 7 is also expressed by equation (4).

$${H}_{2} ( z ) = \frac{{z}^{- 1}}{1 - {a}_{2} {z}^{- 1}} \qquad ( 12 )$$

Here, z represents a complex variable, z⁻¹ represents a delay in the delay circuit 13, and a2 represents the second feedback coefficient.

In the second processing phase, quantization is performed with the output Aout[n] in the first processing phase remaining as a residual component. In the second processing phase, the controller 4 applies the output signal Aout[n] in the first integration operation to the second integration operation. Therefore, the output Din of the quantizer 5 by the second integration operation in the second processing phase is derived by the following equations (13) to (15).

$${A}_{o u t} ( z ) = {a}_{2} {A}_{o u t} [ n ] + {H}_{2} ( {A}_{s i g} ( z ) - {D}_{i n} ( z ) ) \qquad ( 13 )$$

$$\frac{{z}^{- 1}}{1 - {a}_{2} {z}^{- 1}} {D}_{i n} ( z ) = \frac{{z}^{- 1}}{1 - {a}_{2} {z}^{- 1}} {A}_{s i g} ( z ) + {a}_{2} \frac{{z}^{- 1}}{1 - {a}_{2} {z}^{- 1}} {A}_{out} [ n ] - {A}_{out} ( z ) \qquad ( 14 )$$

$${D}_{i n} ( z ) = {A}_{s i g} ( z ) + {a}_{2} {A}_{o u t} [ n ] - \frac{1 - {a}_{2} {z}^{- 1}}{{z}^{- 1}} {A}_{o u t} ( z ) \qquad ( 15 )$$

Accordingly, the digital signal Dout output from the delta-sigma modulator 1 in the second processing phase is expressed by the following equation (16).

$$\begin{matrix}{D}_{o u t} ( z ) = \begin{matrix}{H}_{2} ( z ) * {D}_{in} ( z ) = \frac{{z}^{- 1}}{1 - {a}_{2} {z}^{- 1}} ( {A}_{s i g} ( z ) \\ {a}_{2} {A}_{out} [ n ] - \frac{1 - {a}_{2} {z}^{- 1}}{{z}^{- 1}} {A}_{out} ( z ) )\end{matrix} + \\ = \frac{{z}^{- 1}}{1 - {a}_{2} {z}^{- 1}} {A}_{s i g} ( z ) + {a}_{2} \frac{{z}^{- 1}}{1 - {a}_{2} {z}^{- 1}} {A}_{o u t} [ n ] - {A}_{o u t} ( z )\end{matrix} \qquad ( 16 )$$

Here, with the number of second integration operations in the second processing phase being m, the following equation (17) holds in the second processing phase, where the second feedback coefficient a2 is greater than 1.

$$\frac{{z}^{- 1}}{1 - {a}_{2} {z}^{- 1}} = \frac{{a}_{2}^{m} - 1}{{a}_{2} - 1} \qquad ( 17 )$$

Since the initial values of the first integrator 4 and the second integrator 7 are represented by Aout[n] and Dout[n], the digital signal Dout[m] in the second processing phase is expressed by the following equation (18).

$${D}_{o u t} [ m ] = \frac{{a}_{2}^{m} - 1}{{a}_{2} - 1} {A}_{s i g} + {a}_{2} \frac{{a}_{2}^{m} - 1}{{a}_{2} - 1} {A}_{o u t} [ n ] - {A}_{o u t} [ m ] \qquad ( 18 )$$

Here, n represents the number of the first integration operations performed in the first processing phase and m represents the number of the first integration operations performed in the second processing phase.

By deleting Aout[n] from equations (10) and (18), the following equation (19) is obtained.

$${D}_{o u t} [ m ] + {a}_{2} \frac{{a}_{2}^{m} - 1}{{a}_{2} - 1} {D}_{o u t} [ n ] = {a}_{2} \frac{{a}_{2}^{m} - 1}{{a}_{2} - 1} ( 1 + n ) {A}_{s i g} - {A}_{o u t} [ m ] \qquad ( 19 )$$

As shown in equation (19), the output Dout[n] of the first processing phase and the output Dout[m] of the second processing phase can be expressed by using the input analog signal Asig. In equation (19), the coefficient Asig is expressed as the product of a2, exponentially amplified to the power of m, and n. That is, when the number of first integration operations in the first processing phase is n and the number of second integration operations in the second processing phase is m, the resolution of the delta-sigma modulator 1 is on the order of (a2^{m})*n times Asig. Equation (19) explains that the number of second integration operations in the second processing phase has a greater effect on improving the resolution of the delta-sigma modulator 1 than the number of first integration operations in the first processing phase. Therefore, by increasing the number m of the second integration operations in the second processing phase, the resolution of the delta-sigma modulator 1 is improved.

Since the delta-sigma modulator 1 has a reset operation, the digital signal Dout is expressed in the form of a finite impulse filter (FIR). Therefore, the transfer functions H1 and H2 of the integration filter of the delta-sigma modulator 1 are expressed by the following equations (20) and (21), respectively.

$${H}_{1} ( z ) = {z}^{- 0} + {a}_{1} {z}^{- 1} + … + {a}_{1}^{n} {z}^{- n} \qquad ( 20 )$$

$${H}_{2} ( z ) = {z}^{- 0} + {a}_{2} {z}^{- 1} + … + {a}_{2}^{m} {z}^{- m} \qquad ( 21 )$$

Here, n represents the number of the first integration operations performed in the first processing phase and m represents the number of the second integration operations performed in the second processing phase. Moreover, z represents a complex variable, z^{-t} represents the delay at the t-th sampling. In equations (20) and (21), as the value (absolute value) of the exponent t becomes smaller, the z^{-t} represents more new data.

By substituting z=e^{jω} into equations (20) and (21), the data shown in FIG. 4 are obtained. FIG. 4 is a graph illustrating the transfer functions of the first integration operation and the second integration operation in the sequential operations shown in FIG. 3. Here, FIG. 4 shows the sequential operations with an OSR of 16, while FIG. 3 explains the sequential operations with an OSR of 8. In FIG. 4, the horizontal axis indicates normalized frequency with the bandwidth frequency of the delta-sigma modulator 1 set to 1, and the vertical axis indicates gain applied to the input of the frequency on the horizontal axis. FIG. 4 shows H₁(z) for the case with n=16 and m=0, where only the first integration operation is performed, and H₂(z) for the case with n=0 and m=16, where only the second integration operation is performed. FIG. 4 explains that the first integration operation in the first processing phase has a higher noise reduction filtering effect than the second integration operation in the second processing phase. Therefore, increasing the number n of the first integration operation performed in the first processing phase improves the noise reduction filtering effect of the delta-sigma modulator 1.

FIG. 5 is a graph illustrating the transfer functions with different numbers of second integration operations in the sequential operation shown in FIG. 3. FIG. 5 shows the characteristics of the transfer functions when the number of second integration operations in the second processing phase is varied to 2, 4, and 6 with OSR=16. In FIG. 5, increasing the number of second processing phases shifts the cutoff frequency (−3 dB frequency) toward the higher frequency range. This is because, as shown in FIG. 4, the number of first integration operations with a stronger filtering effect decreases and the number of second integration operations with a weaker filtering effect increases, resulting in an overall reduction in noise suppression filtering effect.

Accordingly, in order to improve the noise reduction filtering effect of the delta-sigma modulator 1, it is necessary to increase the number of first integration operations, while in order to improve the resolution thereof, it is necessary to increase the number of second integration operations. Therefore, in the sequential operation of the delta-sigma modulator 1, the number of first integration operations and the number of second integration operations have a trade-off relationship.

Next, with reference to FIG. 6, the parallel operation of the delta-sigma modulator 1 will be described. With the configuration described above with reference to FIG. 2, the delta-sigma modulator 1 can have two integration process sequences which can be processed in parallel. In the present disclosure, the two integration process sequences which can be processed in parallel are, for example, called a frontend sequence and a backend sequence. Specifically, the controller 9 outputs a clock signal to the first integrator 4 and the second integrator 7. The controller 9 controls the first integrator 4 and the second integrator 7 by associating the first integration operation and the second integration operation with respective half cycles of a clock cycle defined by the clock signal. For example, the two half-cycle of the clock cycle respectively correspond to the two periods φ1 and φ2 (high/low). The periods φ1 and φ2 are also referred to as the first half cycle and the second half cycle, respectively. For example, the period φ1 may be the period used in the frontend sequence and the period φ2 may be the period used in the backend sequence.

As described above, in the delta-sigma modulator 1, the two integration process sequences, the frontend sequence and the backend sequence, can be independent sequences that are processed in parallel. In FIG. 6, as an example, the first processing phase is assigned to the frontend sequence, and the second processing phase is assigned to the backend sequence. In the first integration process, the controller 9 causes the first integrator 4 and the second integrator 7 to execute the reset phase and the first processing phase in the frontend sequence. As a result, the first integrator 4 and the second integrator 7 reset the integration value in the frontend sequence and then execute the first integration operation. Subsequently, the controller 9 carries over the output Aout (integration value) from the first process phase as the residual component to the second process phase, and then, causes the first integrator 4 and the second integrator 7 to start the second process phase in the backend sequence. As a result, the first integrator 4 and the second integrator 7 execute the second integration operation in the backend sequence. Moreover, the controller 9 controls the first integrator 4 and the second integrator 7 to start the second integration process in the frontend sequence in parallel with the second processing phase of the first integration process in the backend sequence. Then, the first integrator 4 and the second integrator 7 reset the integration value in the frontend sequence and then execute the first integration operation.

By repeating above-mentioned control by the controller 9, the first integration operation and the second integration operation are at least partially performed simultaneously at every predetermined period in the delta-sigma modulator 1. The second integration operation may have any time length equal to or shorter than the first integration operation.

FIG. 7 compares the transfer functions in the sequential operation and the parallel operation of the delta-sigma modulator 1. In FIG. 7, the characteristics of the sequential operation and the parallel operation are shown under the condition that the OSR is 16 and the number of second integration processes is set to 6. The line representing sequential operation in FIG. 7 has the same shape as the line representing the sequential operation with 6 second integration operations shown in FIG. 5.

As shown in FIG. 3, the sequential operation requires 16 clock cycles for the first and second processing phases (to generate the digital signal Dout). In contrast, as shown in FIG. 7, the parallel operation requires 22 clock cycles (16+6) for the first and second processing phases, resulting in an increase in the actual processing time. However, by performing the first integration operation and the second integration operation at least partially in parallel, the parallel operation outputs the digital signal Dout at an apparent interval of 16 clock cycles, like the sequential operation.

Accordingly, the delta-sigma modulator 1 can increase the period of the second processing phase (the number of second integration operations) without decreasing the period of the first processing phase (the number of first integration operations) in the parallel operation, compared to the sequential operation. As a result, the parallel operation allows the delta-sigma modulator 1 to reduce noise in the range from lower to higher frequencies compared to serial operation, as shown in FIG. 7.

Therefore, the delta-sigma modulator 1 according to the present disclosure can achieve both an improved resolution and noise reduction filtering effect.

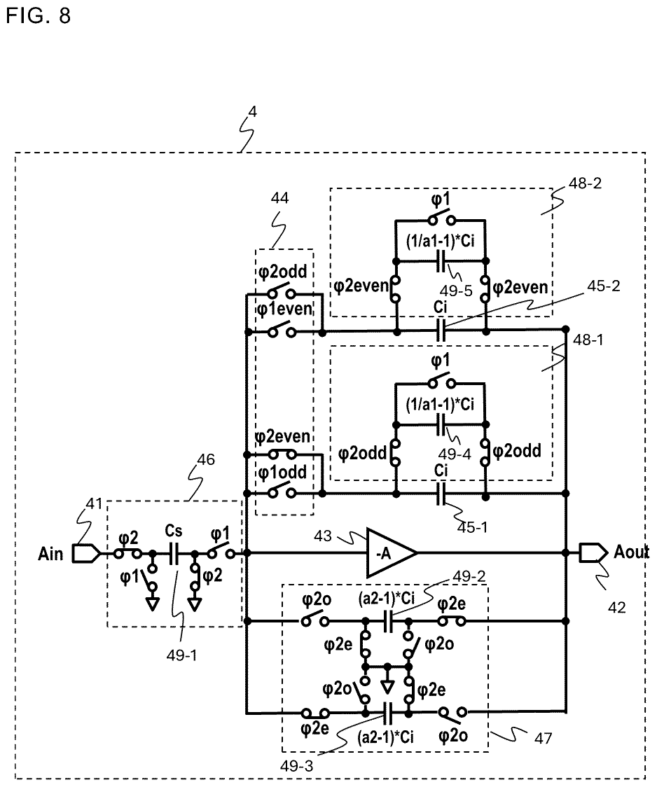

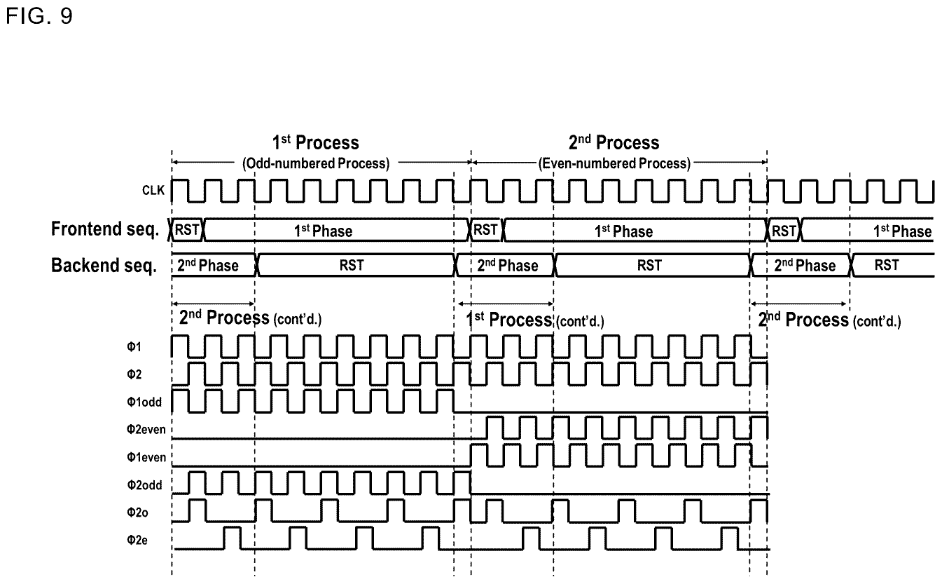

With reference to FIG. 8 and FIG. 9, an example of the circuit configuration of the first integrator 4 that enables parallel operation of the delta-sigma modulator 1 will be described. FIG. 8 illustrates an example of the circuit configuration of the first integrator 4 in the delta-sigma modulator 1 shown in FIG. 1. FIG. 9 shows an example of the parallel operations of the first integrator 1 shown in FIG. 8.

As shown in FIG. 8, the first integrator 4 includes an input terminal 41, an output terminal 42, an amplifier 43, a switch circuit 44, a first feedback capacitor 45-1, a second feedback capacitor 45-2, a first switched capacitor circuit 46, and a second switched capacitor circuit 47. The input terminal 41, the output terminal 42, the amplifier 43, the switch circuit 44, the first feedback capacitor 45-1, the second feedback capacitor 45-2, the first switched capacitor circuit 46, and the second switched capacitor circuit 47 of the first integrator 4 may be controlled by the controller 9. Thus, the controller 9 controls the operation of the first integrator 4.

The amplifier 43 and the first switched capacitor circuit 46 are connected in series between the input terminal 41 and the output terminal 42. The input terminal of the first switched capacitor circuit 46 is connected to the input terminal 41 of the first integrator 4. The input terminal of the amplifier 43 is connected to the output terminal of the first switched capacitor circuit 46. The output terminal of the amplifier 43 is connected to the output terminal 42 of the first integrator 4.

The switch circuit 44, the first feedback capacitor 45-1, and the second feedback capacitor 45-2 are connected in parallel with the amplifier 43 between the first switched capacitor circuit 46 and the output terminal 42. The switch circuit 44 is connected to the input terminal of the amplifier 43 and each of the input terminals of the first feedback capacitor 45-1 and the second feedback capacitor 45-2. Each of the output terminals of the first feedback capacitor 45-1 and the second feedback capacitor 45-2 is connected to the output terminal 42 and the output terminal of the amplifier 43. The first feedback capacitor 45-1 and the second feedback capacitor 45-2 are connected in parallel between the switch circuit 44 and the output terminal 42.

The switch circuit 44 has one or more switches. The switch circuit 44 controls charging and discharging of the first feedback capacitor 45-1 and the second feedback capacitor 45-2. The switch circuit 44 connects one of the first feedback capacitor 45-1 and the second feedback capacitor 45-2 to the input terminal of the amplifier 43. The first feedback capacitor 45-1 and the second feedback capacitor 45-2 store a signal input when the switch of the switch circuit 44 connected thereto is enabled. The first feedback capacitor 45-1 and the second feedback capacitor 45-2 have the same integration capacitance. In this embodiment, the first feedback capacitor 45-1 and the second feedback capacitor 45-2 have a capacitance Ci.

With reference to FIG. 8 and FIG. 9, as an example, the switch circuit 44 connects the first feedback capacitor 45-1 to the amplifier 43 during a period φ1odd, which is a period φ1 in an odd-numbered integration process (for example, a first integration process) among the repeated integration processes, in accordance with the control of the controller 9. As a result, the first feedback capacitor 45-1 functions as a feedback capacitor for the first processing phase of the frontend sequence in the odd-numbered integration process. Moreover, the switch circuit 44 connects the first feedback capacitor 45-1 to the amplifier 43 during a period φ2even, which is a period φ2 in an even-numbered integration process (for example, a second integration process) among the repeated integration processes, in accordance with the control of the controller 9. As a result, the first feedback capacitor 45-1 functions as a feedback capacitor for the second processing phase of the backend sequence in the odd-numbered integration process (shown as 1st Process (cont'd.) in FIG. 6).

Similarly, the switch circuit 44 connects the second feedback capacitor 45-2 to the amplifier 43 during a period φ1even, which is a period 1 in an even-numbered integration process among the repeated integration processes, in accordance with the control of the controller 9. As a result, the second feedback capacitor 45-2 functions as a feedback capacitor for the first processing phase of the frontend sequence in the even-numbered integration process. Moreover, the switch circuit 44 connects the second feedback capacitor 45-2 to the amplifier 43 during a period φ2odd, which is a period φ2 in an odd-numbered integration process among the repeated integration processes, in accordance with the control of the controller 9. As a result, the second feedback capacitor 45-2 functions as a feedback capacitor for the second processing phase of the backend sequence in the even-numbered integration process (shown as 2nd Process (cont'd.) in FIG. 6).

Such an operation of the switch circuit 44 enables the first integrator 4 to transfer the output Aout of the first integration operation in the first processing phase as a residual component to the second integration operation in the second processing phase, simply by switching the switch. This allows the delta-sigma modulator 1 according to the present disclosure to enable a power-efficient transfer without using extra current for transfer.

The first switched capacitor circuit 46 is provided between the input terminal 41 and the input terminal of the amplifier 43. The first switched capacitor circuit 46 repeats charging of the analog signal Ain input to the first integrator 4 and discharging to the amplifier 43 in accordance with the control of the controller 9.

The first switched capacitor circuit 46 comprises a first capacitor 49-1 and one or more switches. The first capacitor 49-1 has a capacitance of Cs. The first switched capacitor circuit 46 repeats the charging and discharging of the first capacitor 49-1 corresponding to two phases, φ1 and φ2 (for example, high/low), which repeat within each clock cycle. For example, during the period φ1, the first switched capacitor circuit 46 may connect the input terminal of the first capacitor 49-1 to the reference potential and connect the output terminal of the first capacitor 49-1 to the input terminal of the amplifier 43, causing the first capacitor 49-1 to discharge. During the period φ2, the first switched capacitor circuit 46 may connect the input terminal of the first capacitor 49-1 to the input terminal 41 of the first integrator 4 and connect the output terminal of the first capacitor 49-1 to a reference potential, causing the first capacitor 49-1 to be charged with an analog signal Ain from the input terminal 41. Here, the first capacitor 49-1 has the input terminal on the input terminal 41 side and the output terminal on the output terminal 42 side.

The second switched capacitor circuit 47 is connected in parallel with the amplifier 43 between the first switched capacitor circuit 46 and the output terminal 42. The second switched capacitor circuit 47 repeats charging of the analog signal Vout as output from the first integrator 4 and discharging to the amplifier 43 in accordance with the control of the controller 9.

The second switched capacitor circuit 47 has a second capacitor 49-2, a third capacitor 49-3, and one or more switches. The capacitance of the second capacitor 49-2 and the third capacitor 49-3 is determined as (a2−1)*Ci, where a2 is the value of the second feedback coefficient and Ci is the capacitance of each of the first feedback capacitor 45-1 and the second feedback capacitor 45-2. This enables the second feedback coefficient a2 in the first integrator 4. That is, the operation of the second feedback circuit 16-2 having the gain a2 in the first integrator 4 is realized. The second feedback coefficient a2 may be greater than or equal to 1. Preferably, the second feedback coefficient a2 may be greater than 1.

For example, during a period φ2o, which is an odd-numbered period φ2 in each integration process, the second switched capacitor circuit 47 connects the input terminal of one of the second capacitor 49-2 or the third capacitor 49-3 to the output terminal 42 of the first integrator 4, connects the output terminal thereof to a reference potential, and charges the output signal Vout from the output terminal 42. Additionally, during the period φ2o, the second switched capacitor circuit 47 connects the input terminal of the other one of the second capacitor 49-2 or the third capacitor 49-3 to a reference potential, connects the output terminal thereof to the input terminal of the amplifier 43, and discharges the charge stored in the previous period φ2 (φ2e). Furthermore, during a period φ2e, which is an even-numbered period φ2 in each integration process, the second capacitor 49-2 and the third capacitor 49-3 reverse their roles from those during period φ2o to perform charging or discharging. In this way, the second switched capacitor circuit 47 repeats the operation during the period φ2 to charge and discharge the second capacitor 49-2 repeatedly and the third capacitor 49-3. That is, the second switched capacitor circuit 47 enables the second integration operation having the second feedback coefficient a2 by the first integrator 4 during the period φ2.

In the capacitance (a2−1)*Ci of the second capacitor 49-2 and the third capacitor 49-3, the value a2 may be configured to be variable. That is, the second feedback coefficient a2 of the first integrator 4 may be configured to be variable.

The second capacitor 49-2 and the third capacitor 49-3 may be a variable capacitor. That is, the first integrator 4 may comprise a variable capacitor. This allows the capacitance of each of the second capacitor 49-2 and the third capacitor 49-3 to be varied according to the voltage applied thereto, thereby enabling the second feedback coefficient a2 of the first integrator 4 to be variable. The controller 9 may vary the capacitances of the second capacitor 49-2 and the third capacitor 49-3 to vary the second feedback coefficient a2 of the first integrator 4.

As shown in FIG. 8, the first integrator 4 may further comprise a third switched capacitor circuit 48-1 and a fourth switched capacitor circuit 48-2. The third switched capacitor circuit 48-1 and the fourth switched capacitor circuit 48-2 may be controlled by the controller 9.

The third switched capacitor circuit 48-1 is connected in parallel with the first feedback capacitor 45-1. The input terminal of the third switched capacitor circuit 48-1 is connected to the switch circuit 44, and the output terminal of the third switched capacitor circuit 48-1 is connected to the output terminal 42 and the output terminal of the amplifier 43.

The third switched capacitor circuit 48-1 comprises a fourth capacitor 49-4 and one or more switches. The capacitance of the fourth capacitor 49-4 is determined as (1/a1−1)*Ci, where a1 is the value of the first feedback coefficient and Ci is the capacitance of the first feedback capacitor 45-1. The third switched capacitor circuit 48-1 repeats charging and discharging of the fourth capacitor 49-4 in accordance with the control of the controller 9.

For example, during a period φ1 the third switched capacitor circuit 48-1 shorts both terminals of the fourth capacitor 49-4, causing the fourth capacitor 49-4 to discharge. During a period φ2odd, which is a period φ2 in an odd-numbered integration process among the repeated integration processes, the third switched capacitor circuit 48-1 connects one terminal of the fourth capacitor 49-4 to one terminal of the first feedback capacitor 45-1 and the other terminal of the fourth capacitor 49-4 to the other terminal of the first feedback capacitor 45-1, causing the fourth capacitor 49-4 to be charged with the charge discharged by the first feedback capacitor 45-1. The third switched capacitor circuit 48-1 repeats the operations during the periods φ1 and φ2odd to repeatedly charge and discharge the fourth capacitor 49-4, thereby enabling the first feedback coefficient a1 in the first integrator 4. That is, the operation of the first feedback circuit 16-1 having the gain a1 in the first integrator 4 is realized. The first feedback coefficient a1 may be greater than 0 and less than or equal to 1. Preferably, the first feedback coefficient a1 may be greater than 0 and less than 1.

The fourth switched capacitor circuit 48-2 is connected in parallel with the second feedback capacitor 45-2. The input terminal of the fourth switched capacitor circuit 48-2 is connected to the switch circuit 44, and the output terminal of the fourth switched capacitor circuit 48-2 is connected to the output terminal 42 and the output terminal of the amplifier 43.

The fourth switched capacitor circuit 48-2 comprises a fifth capacitor 49-5 and one or more switches. The capacitance of the fifth capacitor 49-5 is determined as (1/a1−1)*Ci, where a1 is the value of the first feedback coefficient and Ci is the capacitance of the second feedback capacitor 45-2. The fourth switched capacitor circuit 48-2 repeats charging and discharging of the fifth capacitor 49-5 in accordance with the control of the controller 9.

For example, during a period φ1 the fourth switched capacitor circuit 48-2 shorts both terminals of the fifth capacitor 49-5, causing the fifth capacitor 49-5 to discharge. During a period φ2even, which is a period φ2 in an even-numbered integration process among the repeated integration processes, the fourth switched capacitor circuit 48-2 connects one terminal of the fifth capacitor 49-5 to one terminal of the second feedback capacitor 45-2 and the other terminal of the fifth capacitor 49-5 to the other terminal of the second feedback capacitor 45-2, causing the fifth capacitor 49-5 to be charged with the charge discharged by the second feedback capacitor 45-2. The fourth switched capacitor circuit 48-2 repeats the operations during the periods φ1 and φ2even to repeatedly charge and discharge the fifth capacitor 49-5, thereby enabling the first feedback coefficient a1 in the first integrator 4. That is, the operation of the first feedback circuit 16-1 having the gain a1 in the first integrator 4 is realized. The first feedback coefficient a1 may be greater than 0 and less than or equal to 1. More preferably, the first feedback coefficient a1 may be greater than 0 and less than 1.

In the capacitance (1/a1−1)*Ci of the fourth capacitor 49-4 and the fifth capacitor 49-5, the value a1 may be configured to be variable. That is, the first feedback coefficient a1 of the first integrator 4 may be configured to be variable.

The fourth capacitor 49-4 and the fifth capacitor 49-5 may be a variable capacitor. That is, the first integrator 4 may comprise a variable capacitor. This allows the capacitance of each of the fourth capacitor 49-4 and the fifth capacitor 49-5 to be varied according to the voltage applied thereto, thereby enabling the first feedback coefficient a1 of the first integrator 4 to be variable. The controller 9 may vary the capacitances of the fourth capacitor 49-4 and the fifth capacitor 49-5 to vary the first feedback coefficient a1 of the first integrator 4.

With reference to FIG. 9, an example of parallel operation by the first integrator 4 having the above-mentioned configuration will be described. The controller 9 outputs a clock signal to the first integrator 4 to control the operation of the first integrator 4 in accordance with clock cycles determined by the clock signal. In FIG. 9, as an example, the controller 9 controls the first integrator 4 to perform the first integration operation in the frontend sequence associated with the first half cycle of the clock cycle (period φ1). The controller 9 controls the first integrator 4 to perform the second integration operation in the backend sequence associated with the second half cycle of the clock cycle (period φ2).

As shown in FIG. 9, the controller 9 causes the first integrator 4 to repeatedly execute the first integration process and the second integration process. Here, the first integration process is an odd-numbered integration process among the repeated integration processes, and the second integration process is an even-numbered integration process among the repeated integration processes.

First, the controller 9 starts a first integration process among the repeated integration processes. Specifically, in the front-end sequence, the controller 9 resets the first feedback capacitor 45-1 and starts a first integration operation using the reset first feedback capacitor 45-1. The first integration operation is an integration operation performed by the first integrator 4 as an integrator having a first feedback coefficient a1. In the first integration operation, the controller 9 repeats charging the first feedback capacitor 45-1 with an analog signal and controlling the third switched capacitor circuit 48-1 to amplify and output the analog signal from the first feedback capacitor 45-1 by a gain a1.

Next, the controller 9 starts the second integration process following the first integration process among the integration processes. Upon starting the second integration process, the controller 9 switches the execution of the first integration process from the frontend sequence to the backend sequence. Specifically, after executing the first integration operation using the first feedback capacitor 45-1, in the frontend sequence, the controller 9 starts the second integration operation using the first feedback capacitor 45-1 having the residual voltage generated by the first integral operation, in the backend sequence. The second integration operation is an integration operation performed by the first integrator 4 as an integrator having a second feedback coefficient a2. In the second integration operation, the controller 9 repeats charging the first feedback capacitor 45-1 with an analog signal and controlling the second switched capacitor circuit 47 to amplify and output the analog signal from the first feedback capacitor 45-1 by a gain a2. Moreover, the controller 9 resets the second feedback capacitor 45-2 and starts the first integration operation using the reset second feedback capacitor 45-2, in the frontend sequence.

Then, the controller 9 starts again the first integration process following the second integration process. Upon starting the first integration process, the controller 9 switches the execution of the second integration process from the frontend sequence to the backend sequence. Specifically, after executing the first integration operation using the second feedback capacitor 45-2 in the frontend sequence, the controller 9 starts the second integration operation using the second feedback capacitor 45-2 having the residual voltage generated by the first integral operation, in the backend sequence. In the second integration operation, the controller 9 repeats charging the second feedback capacitor 45-2 with an analog signal and controlling the second switched capacitor circuit 47 to amplify and output the analog signal from the second feedback capacitor 45-2 by a gain a2. Moreover, the controller 9 resets the first feedback capacitor 45-1 and starts the first integration operation using the reset first feedback capacitor 45-1 in the frontend sequence.

In this manner, the controller 9 causes the first integrator 4 to perform the first integration operation in the frontend sequence and the second integration operation in the backend sequence at least partially simultaneously, thereby enabling the parallel operation by the first integrator 4.

With reference again to FIG. 2, an example of the circuit configuration of the second integrator 7 that enables parallel operation of the delta-sigma modulator 1 will be described. The second integrator 7, which is a digital integrator, may include a first logic circuit for amplifying an input digital signal by the gain a1, as the first feedback circuit 16-1. Specifically, the first logic circuit as the first feedback circuit 16-1 performs a bit shift processing and an addition processing on the input digital signal to amplify the input digital signal by the gain a1. The first logic circuit may be configured to change the bit shift calculation processing and the addition processing to vary the gain a1 in accordance with control by the controller 9. That is, the second integrator 7 may comprise a first logic circuit configured to vary the feedback coefficient a1.

The second integrator 7 may also include a second logic circuit for amplifying an input digital signal by the gain a2, as the second feedback circuit 16-2. Specifically, the second logic circuit as the second feedback circuit 16-2 performs a bit shift processing and an addition processing on the input digital signal to amplify the input digital signal by the gain a2. The second logic circuit may be configured to change the bit shift calculation processing and the addition processing to dynamically vary the gain a2 in accordance with control by the controller 9. That is, the second integrator 7 may comprise a second logic circuit configured to dynamically vary the feedback coefficient a2.

In this manner, the controller 9 causes the second integrator 7 to perform the first integration operation and the second integration operation at least partially simultaneously, thereby enabling the parallel operation by the second integrator 7.

In the integrator 10 (first integrator 4, second integrator 7) of the delta sigma modulator 1 according to the present disclosure, the gain a1 of the first feedback circuit 16-1 and/or the gain a2 of the second feedback circuit 16-2 may be constant during a series of integration operations. That is, the first feedback coefficient a1 and/or the second feedback coefficient a2 of the integrator 10 (first integrator 4, second integrator 7) may be constant during the series of integration operations. Alternatively, the gain a1 of the first feedback circuit 16-1 and/or the gain a2 of the second feedback circuit 16-2 may be dynamically varied during a series of integration operations, in accordance with the control of the controller 9. That is, the first feedback coefficient a1 and/or the second feedback coefficient a2 may be dynamically changed during a series of integration operations, in accordance with the control of the controller 9. More specifically, the first feedback coefficient a1 and/or the first feedback coefficient a2 of the integrator 10 (first integrator 4, the second integrator 7) may be configured to be varied according to each integration operation included in the series of integration operations. Such a delta-sigma modulator 1 allows for more precise design of the resolution and filtering effect by dynamically varying the first feedback coefficient a1 and/or the second feedback coefficient a2 during the series of integral operations.

As described above with reference to the accompanying drawings, a delta-sigma modulator 1 comprises: a first integrator 4 configured to integrate an analog signal; a quantizer 5 configured to quantize a signal output from the first integrator 4; a DA converter 6 configured to convert a digital signal output from the quantizer 5 into a feedback analog signal and output the feedback analog signal to the first integrator 4; and a controller 9 configured to control the first integrator 4 to repeatedly perform a series of integration operations. In the delta-sigma modulator 1, the series of integration operations includes at least a first integration operation and a second integration operation. In the delta-sigma modulator 1, the controller 9 is configured to: control the first integrator 4 to perform the first integration operation as an integrator having a first feedback coefficient a1; control the first integrator 4 to perform the second integration operation as an integrator having a second feedback coefficient a2; and perform the first integration operation and the second integration operation at least partially simultaneously.

Such delta-sigma modulator 1 can achieve both high resolution and high filtering effect. Moreover, the delta-sigma modulator 1 according to the present disclosure can achieve the required resolution and the required filtering effect by adjusting the first feedback coefficient a1 and the second feedback coefficient a2. Therefore, the present disclosure can provide a delta-sigma modulator 1 with improved utility.

While the present disclosure has been described with reference to the drawings and examples, it should be noted that various modifications and revisions may be implemented by those skilled in the art based on the present disclosure. Accordingly, such modifications and revisions are included within the scope of the present disclosure. For example, configurations, functions, or the like included in each embodiment can be rearranged without logical inconsistency. In addition, configurations or functions included in each embodiment can be used in combination with another embodiment, and multiple configurations or functions can be combined into one, divided, or partially omitted.

### REFERENCE SIGNS IN FIGURES

1: Delta-sigma modulator,
2: Input terminal,
3: Adder-subtractor,
4: First integrator,
5: Quantizer,
6: DA converter (Digital-to-Analog converter),
7: Second integrator,
8: Output terminal,
9: Controller,
10: Integrator,
11: Input terminal,
12: Adder,
13: Delay circuit,
14: First switch circuit,
15: Reset circuit,
16-1: First feedback circuit,
16-2: Second feedback circuit,
17: Second switch circuit,
18: Output terminal,
19: Feedback path,
41: Input terminal,
42: Output terminal,
43: Amplifier,
44: Switch circuit,
45-1: First feedback capacitor,
45-2: Second feedback capacitor,
46: First switched capacitor circuit,
47: Second switched capacitor circuit,
48-1: Third switched capacitor circuit,
48-2: Fourth switched capacitor circuit,
49-1: First capacitor,
49-2: Second capacitor,
49-3: Third capacitor,
49-4: Fourth capacitor,
49-5: Fifth capacitor,
Ci, Cs: Capacitance,
Asig, Ain, Aout, Afb: Analog signal,
Din, Dout: Digital signal, and
Vin, Vout, Vout1, Vout2, Vfb, Vsum, Vout_0: Signal.

1. A delta-sigma modulator comprising:
a first integrator configured to integrate an analog signal;
a quantizer configured to quantize a signal output from the first integrator;
a DA (Digital-to-Analog) converter configured to convert a digital signal output from the quantizer into a feedback analog signal and output the feedback analog signal to the first integrator; and
a controller configured to control the first integrator to repeatedly perform a series of integration operations, wherein
the series of integration operations includes at least a first integration operation and a second integration operation, and
the controller is configured to:
control the first integrator to perform the first integration operation as an integrator having a first feedback coefficient;
control the first integrator to perform the second integration operation as an integrator having a second feedback coefficient; and
perform the first integration operation and the second integration operation at least partially simultaneously.

2. The delta-sigma modulator according to claim 1, wherein
the controller is configured to apply an output signal from the first integration operation to the second integration operation.

3. The delta-sigma modulator according to claim 1, wherein
the first feedback coefficient is greater than 0 and less than or equal to 1, and the second feedback coefficient is greater than or equal to 1.

4. The delta-sigma modulator according to claim 3, wherein the first feedback coefficient is greater than 0 and less than 1.

5. The delta-sigma modulator according to claim 3, wherein the second feedback coefficient is greater than 1.

6. The delta-sigma modulator according to claim 1, wherein
the first feedback coefficient is configured to be variable.

7. The delta-sigma modulator according to claim 6, wherein
the first integrator comprises a variable capacitor, and
the first feedback coefficient is configured to be varied according to each integration operation included in the series of integration operations.

8. The delta-sigma modulator according to claim 1, wherein
the controller is configured to:
output a clock signal to the first integrator; and
control the first integrator by associating the first integration operation and the second integration operation with respective half cycles of a clock cycle defined by the clock signal.

9. The delta-sigma modulator according to claim 8, wherein
the first integrator comprises a first feedback capacitor and a second feedback capacitor,
the controller is configured to:
after executing the first integration operation using the first feedback capacitor, in a frontend sequence associated with a first half cycle of the clock cycle,
start the second integration operation using the first feedback capacitor having a residual voltage generated by the first integral operation, in a backend sequence associated with a second half cycle of the clock cycle, and
reset the second feedback capacitor and start the first integration operation using the reset second feedback capacitor, in the frontend sequence; and
after executing the first integration operation using the second feedback capacitor in the frontend sequence,
start the second integration operation using the second feedback capacitor having a residual voltage generated by the first integral operation in the backend sequence, and
reset the first feedback capacitor and start the first integration operation using the reset first feedback capacitor, in the frontend sequence.

10. The delta-sigma modulator according to claim 1 further comprising: a second integrator configured to integrate the digital signal from the quantizer.

11. The delta-sigma modulator according to claim 1, further comprising:
an input terminal configured to receive an analog signal; and
an adder-subtractor configured to subtract the feedback analog signal from the DA converter from the analog signal received at the input terminal to generate a subtracted analog signal and output the subtracted analog signal to the first integrator.

12. A control method for a delta-sigma modulator, the delta-sigma modulator comprising:
a first integrator configured to integrate an analog signal;
a quantizer configured to quantize a signal output from the first integrator;
a DA (Digital-to-Analog) converter configured to convert a digital signal output from the quantizer into a feedback analog signal and output the feedback analog signal to the first integrator; and
a controller configured to control the first integrator to repeatedly perform a series of integration operations, wherein
the series of integration operations includes at least a first integration operation and a second integration operation, and
the control method comprises:
controlling, by the controller, the first integrator to perform the first integration operation as an integrator having a first feedback coefficient;
controlling, by the controller, the first integrator to perform the second integration operation as an integrator having a second feedback coefficient; and
performing, by the controller, the first integration operation and the second integration operation at least partially simultaneously.
